(19) United States
(12) Patent Application Publication
(10) Pub. No.: US 2025/0081668 A1
(43) Pub. Date: Mar. 6, 2025

(54) CHIP PACKAGE AND MANUFACTURING METHOD THEREOF

(71) Applicant: XINTEC INC., Taoyuan City (TW)

(72) Inventors: Wei-Luen SUEN, Taoyuan City (TW); Po-Jung CHEN, Kouhu Township (TW); Jiun-Yen LAI, Taoyuan City (TW); Tsang Yu LIU, Zhubei City (TW)

(21) Appl. No.: 18/803,566

(22) Filed: Aug. 13, 2024

Related U.S. Application Data
(60) Provisional application No. 63/580,332, filed on Sep. 1, 2023.

(51) Int. Cl. H01L 31/02; H01L 21/66; H01L 31/0216; H01L 31/18

(52) U.S. Cl. CPC H10F 77/93; H01L 22/14; H01L 22/32; H10F 71/137; H10F 77/30

(57) ABSTRACT

A chip package includes a semiconductor substrate, an anti-reflection layer, and a metal multi-layer. The semiconductor substrate has an optical sensing area. The anti-reflection layer is located on the semiconductor substrate. The metal multi-layer is located on and in contact with the anti-reflection layer. The metal multi-layer includes a redistribution line and two probe pads. Two ends of the redistribution line respectively extend to the two probe pads. The redistribution line is located in the optical sensing area, and the two probe pads are located outside the optical sensing area. The orthographic projection area of the redistribution line in the optical sensing area is less than 1% of the area of the optical sensing area.

### CROSS-REFERENCE TO RELATED APPLICATIONS

This application claims priority to U.S. Provisional Application Ser. No. 63/580,332, filed Sep. 1, 2023, which is herein incorporated by reference.

### BACKGROUND

### Field of Invention

The present disclosure relates to a chip package and a manufacturing method of the chip package.

### Description of Related Art

Generally speaking, before a wafer is diced into a chip package with optical sensing function, plural optical sensing areas of the wafer should be inspected, such as optical inspection and electrical (resistance) inspection, to determine whether there is cracking or damage before dicing the wafer.

However, before dicing wafer, an indium tin oxide (ITO) layer is usually formed on the anti-reflection layer of the wafer to serve as conductive lines in the optical sensing area. Thereafter, a tetraethyl orthosilicate (TEOS) oxide layer, a silicon nitride layer and an oxide layer are sequentially formed on the indium tin oxide layer, which is a stacked oxide-nitride-oxide (ONO) structure to protect the indium tin oxide layer. Afterwards, an opening can be formed in the oxide-nitride-oxide structure outside the optical sensing area to expose the indium tin oxide layer. In subsequent steps, a redistribution layer can be formed on the oxide layer and the indium tin oxide layer that is in the opening to serve as a probe pad outside the optical sensing area. However, in order to attach to the indium tin oxide layer, the redistribution layer should include a buffer layer (e.g., a titanium nitride (TiN) layer). The above process steps are complicated (multiple deposition and etch steps), making it difficult to reduce the cost of inspecting wafer.

### SUMMARY

One aspect of the present disclosure provides a chip package.

According to some embodiments of the present disclosure, a chip package includes a semiconductor substrate, an anti-reflection layer, and a metal multi-layer. The semiconductor substrate has an optical sensing area. The anti-reflection layer is located on the semiconductor substrate. The metal multi-layer is located on and in direct contact with the anti-reflection layer. The metal multi-layer includes a redistribution line and two probe pads. Two ends of the redistribution line respectively extend to the two probe pads. The redistribution line is located in the optical sensing area, and the two probe pads are located outside the optical sensing area. The orthographic projection area of the redistribution line in the optical sensing area is less than 1% of the area of the optical sensing area.

In some embodiments, the redistribution line of the metal multi-layer includes a plurality of rows, and a gap between adjacent two of the rows of the redistribution line is less than 150 μm.

In some embodiments, the redistribution line of the metal multi-layer is zigzag or wavy.

In some embodiments, the metal multi-layer includes a lower metal layer and an upper metal layer, and the lower metal layer is located between the anti-reflection layer and the upper metal layer.

In some embodiments, a material of the lower metal layer is titanium, and a material of the upper metal layer is gold.

In some embodiments, a sidewall of the upper metal layer is aligned with a sidewall of the lower metal layer.

In some embodiments, the upper metal layer is separated from the anti-reflection layer.

One aspect of the present disclosure provides a manufacturing method of a chip package.

According to some embodiments of the present disclosure, a manufacturing method of a chip package includes forming an anti-reflection layer on a semiconductor substrate, wherein the semiconductor substrate has an optical sensing area; forming a metal multi-layer on the anti-reflection layer, wherein the metal multi-layer is in direct contact with the anti-reflection layer; and patterning the metal multi-layer such that the metal multi-layer includes a redistribution line and two probe pads, wherein two ends of the redistribution line are respectively extend to the two probe pads, the redistribution line is located in the optical sensing area, the two probe pads are located outside the optical sensing area, and an orthographic projection area of the redistribution line in the optical sensing area is less than 1% of an area of the optical sensing area.

In some embodiments, forming the metal multi-layer on the anti-reflection layer includes forming a lower metal layer on the anti-reflection layer, wherein a material of the lower metal layer is titanium; and forming an upper metal layer on the lower metal layer, wherein a material of the upper metal layer is gold.

In some embodiments, patterning the metal multi-layer includes forming a photoresist layer that is patterned on the upper metal layer, wherein a position of the photoresist layer corresponds to a position of the redistribution line and positions of the two probe pads.

In some embodiments, patterning the metal multi-layer further includes etching the upper metal layer and the lower metal layer to form the redistribution line and the two probe pads by using the photoresist layer as a mask; and removing the photoresist layer.

In some embodiments, patterning the metal multi-layer is performed such that the redistribution line includes a plurality of rows, and a gap between adjacent two of the rows of the redistribution line is less than 150 μm.

In some embodiments, patterning the metal multi-layer is performed such that the redistribution line of the metal multi-layer is zigzag or wavy.

In some embodiments, the manufacturing method of the chip package further includes using two probes to respectively be in contact with the two probe pads to measure a resistance of the metal multi-layer.

In some embodiments, the manufacturing method of the chip package further includes after measuring the resistance of the metal multi-layer, dicing the semiconductor substrate.

In the aforementioned embodiments of the present disclosure, since the redistribution line and the two probe pads can be simultaneously formed by patterning after the metal multi-layer is formed on the anti-reflection layer, a conventional indium tin oxide layer, a conventional oxide-nitride-oxide (ONO) structure, and a conventional redistribution layer having a buffer layer can be omitted, thereby omitting plural deposition and etch steps. Moreover, the two probe pads outside the optical sensing area can respectively abut against two probes to measure the resistance of the redistribution line in the optical sensing area, thereby determining whether there is any crack or damage before dicing the semiconductor substrate. In addition, the orthographic projection area of the redistribution line in the optical sensing area less than 1% of the area of the optical sensing area can ensure that the light transmittance of the optical sensing area is greater than 99%.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a cross-sectional view of a semiconductor substrate which is not yet diced according to one embodiment of the present disclosure.

FIG. 2 is a top view of a chip package according to one embodiment of the present disclosure.

FIG. 3 is a cross-sectional view of the chip package taken along line 3-3 of FIG. 2.

FIG. 4 is a cross-sectional view of the chip package taken along line 4-4 of FIG. 2.

FIG. 5 is a flow chart of a manufacturing method of a chip package according to one embodiment of the present disclosure.

FIG. 6 to FIG. 9 are cross-sectional views at intermediate stages of the manufacturing method of the chip package of FIG. 2.

FIG. 10 is a schematic view of an operation of measuring a resistance after a structure of FIG. 9 is formed.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

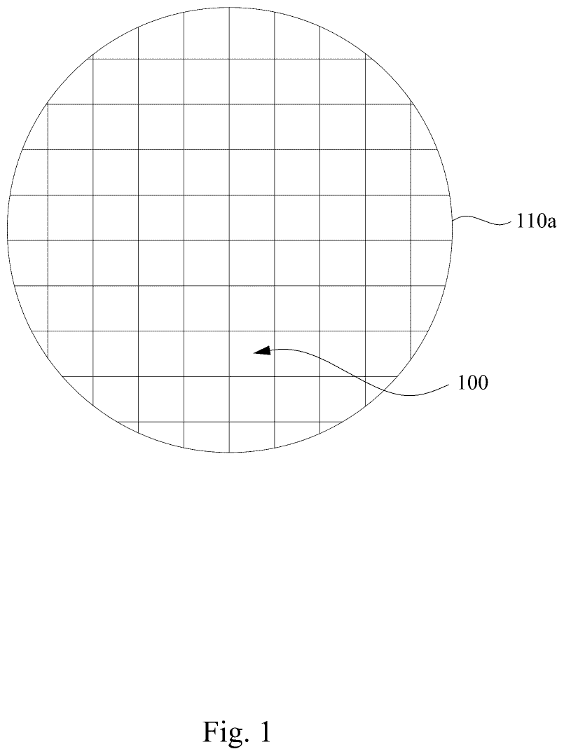

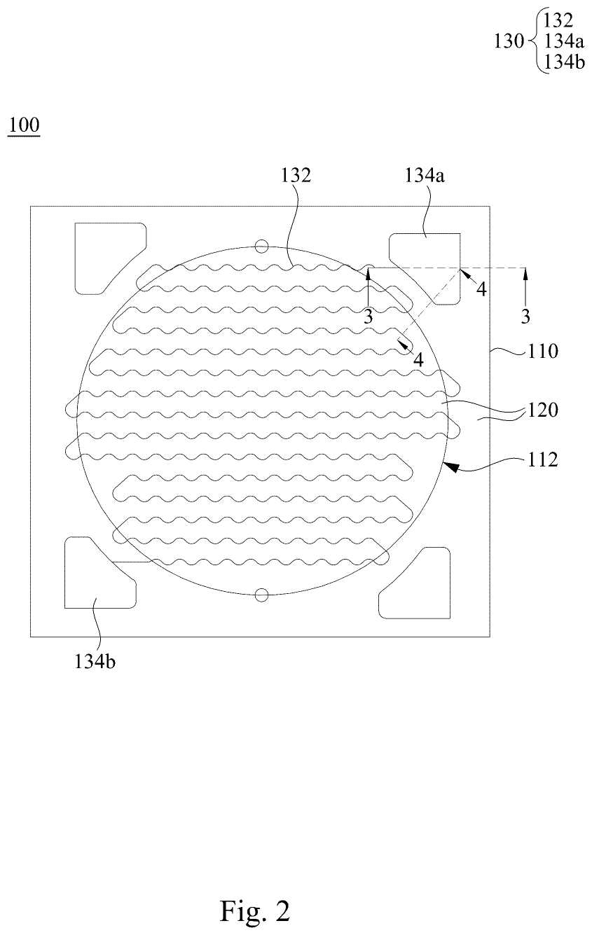

FIG. 1 is a cross-sectional view of a semiconductor substrate 110a which is not yet diced according to one embodiment of the present disclosure. FIG. 2 is a top view of a chip package 100 according to one embodiment of the present disclosure. As shown in FIG. 1 and FIG. 2, the semiconductor substrate 110a is wafer-level size, and the material of the semiconductor substrate 110a includes silicon, such as a silicon wafer. The semiconductor substrate 110 is referred to as a portion of the semiconductor substrate 110a after dicing. The semiconductor substrate 110a may be processed in wafer-level size, and plural chip packages 100 can be formed after dicing, in which a single chip package 100 is shown in FIG. 2.

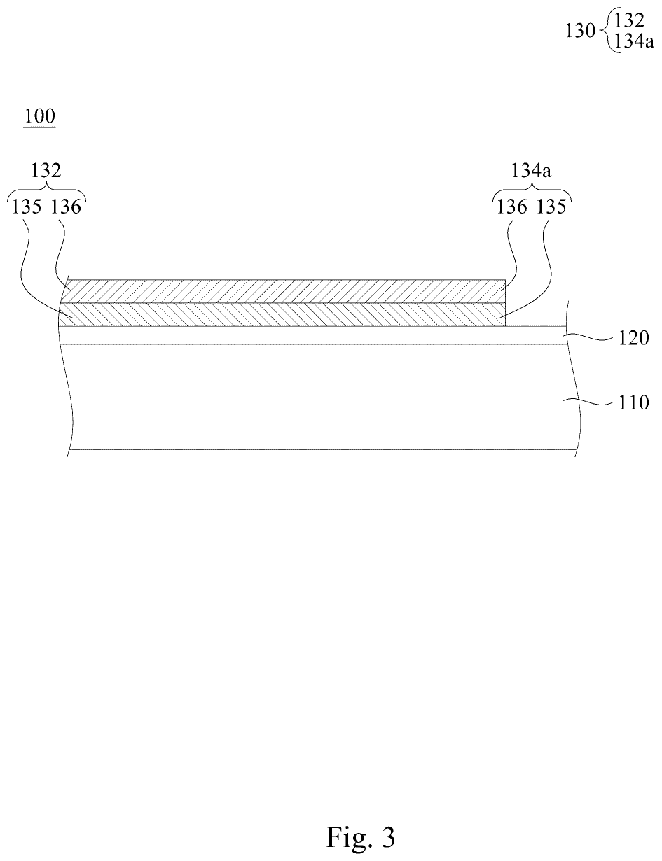

FIG. 3 is a cross-sectional view of the chip package 100 taken along line 3-3 of FIG. 2. As shown in FIG. 2 and FIG. 3, the chip package 100 includes the semiconductor substrate 110, an anti-reflection layer 120, and a metal multi-layer 130. The semiconductor substrate 110 has an optical sensing area 112. The anti-reflection layer 120 is located on the semiconductor substrate 110. The metal multi-layer 130 is located on and in direct contact with the anti-reflection layer 120. The metal multi-layer 130 includes a redistribution line 132 and two probe pads 134a and 134b. Although FIG. 3 takes the probe pad 134a as an example, the structure of the probe pad 134b is also as shown in the probe pad 134a. Two ends of the redistribution line 132 respectively extend to the two probe pads 134a and 134b. In other words, the redistribution line 132 is electrically connected to the two probe pads 134a and 134b. Moreover, the redistribution line 132 is located in the optical sensing area 112, and the two probe pads 134a and 134b are located outside the optical sensing area 112 for being in contact with probes. The orthographic projection area of the redistribution line 132 in the optical sensing area 112 is less than 1% of the area of the optical sensing area 112.

The metal multi-layer 130 includes a lower metal layer 135 and an upper metal layer 136, and the lower metal layer 135 is located between the anti-reflection layer 120 and the upper metal layer 136. In this embodiment, the material of the lower metal layer 135 is titanium, and the material of the upper metal layer 136 is gold. In such a configuration, the lower metal layer 135 can provide adhesion force to omit a traditional buffer layer (e.g., titanium nitride layer), and the upper metal layer 136 can provide protection to prevent the lower metal layer 135 from oxidation. The redistribution line 132 and each of the two probe pads 134a and 134b are defined by the lower metal layer 135 and the upper metal layer 136, merely different in the position and pattern. The upper metal layer 136 of the redistribution line 132, the upper metal layer 136 of the probe pad 134a, and the upper metal layer 136 of the probe pad 134b are formed in the same step, and they are the same layer and integrally formed. The lower metal layer 135 of the redistribution line 132, the lower metal layer 135 of the probe pad 134a, and the lower metal layer 135 of the probe pad 134b are formed in the same step, and they are the same layer and integrally formed. For example, the right side of the dotted line of FIG. 3 is the probe pad 134a, the left side of the dotted line is the redistribution line 132, the lower metal layers 135 of the probe pad 134a and the redistribution line 132 are adjacent to each other, and the upper metal layers 136 of the probe pad 134a and the redistribution line 132 are adjacent to each other, but the patterns viewed from above are different. As shown in FIG. 2, the probe pad 134a is block-shaped, and the line width of the redistribution line 132 is much smaller than the width of the probe pad 134a.

Specifically, since the redistribution line 132 and the two probe pads 134a and 134b can be simultaneously formed by patterning after the metal multi-layer 130 is formed on the anti-reflection layer 120, a conventional indium tin oxide layer, a conventional oxide-nitride-oxide (ONO) structure, and a conventional redistribution layer having a buffer layer can be omitted, thereby omitting plural deposition and etch steps. Moreover, the two probe pads 134a and 134b outside the optical sensing area 112 can respectively abut against two probes to measure the resistance of the redistribution line 132 in the optical sensing area 112, thereby determining whether there is any crack or damage before dicing the semiconductor substrate 110a. In addition, the orthographic projection area of the redistribution line 132 in the optical sensing area 112 (i.e., the area where the redistribution line 132 overlaps with the optical sensing area 112) less than 1% of the area of the optical sensing area 112 can ensure that the light transmittance of the optical sensing area 112 is greater than 99%. As a result, the reliability of the chip package 100 and product competitiveness can be improved.

In some embodiments, the redistribution line 132 of the metal multi-layer 130 includes a plurality of rows, and a gap (spacing) between adjacent two of the rows of the redistribution line 132 is less than 150 μm, and the rows may be parallel. The redistribution line 132 of the metal multi-layer 130 in the optical sensing area 112 is zigzag or wavy. Through the aforementioned configuration, the redistribution line 132 can be uniformly distributed in the optical sensing area 112, thereby ensuring that there is no crack or damage in the entire optical sensing area 112 when a normal resistance is measured, and reducing the possibility of a cracked damaged area without redistribution line 132.

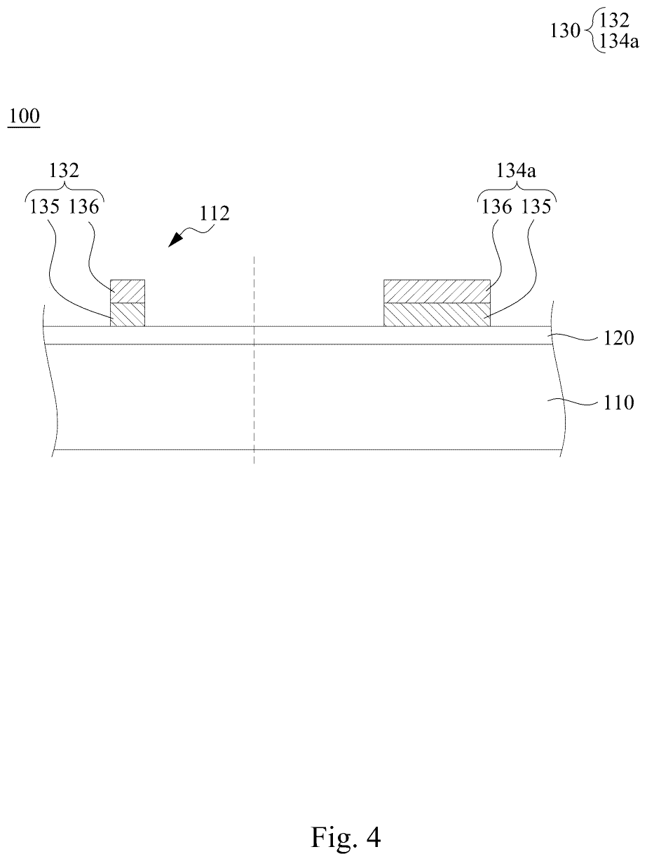

FIG. 4 is a cross-sectional view of the chip package 100 taken along line 4-4 of FIG. 2. The left side of the dotted line of FIG. 4 is an area in the optical sensing area 112, and the right side of the dotted line is an area outside the optical sensing area 112. The lower metal layers 135 and the upper metal layer 136 of the redistribution line 132 of the metal multi-layer 130 are located in the optical sensing area 112, and the lower metal layers 135 and the upper metal layer 136 of the probe pad 134a of the metal multi-layer 130 are located outside the optical sensing area 112. The sidewall of the upper metal layer 136 is aligned with the sidewall of the lower metal layer 135 in a vertical direction, and the sidewall of the lower metal layer 135 is exposed and not covered by the upper metal layer 136. In other words, the upper metal layer 136 does not extend to the anti-reflection layer 120, and the upper metal layer 136 is separated from the anti-reflection layer 120.

It is to be noted that the connection relationships, the materials, and the advantages of the elements described above will not be repeated in the following description. In the following description, the manufacturing method of the chip package will be explained.

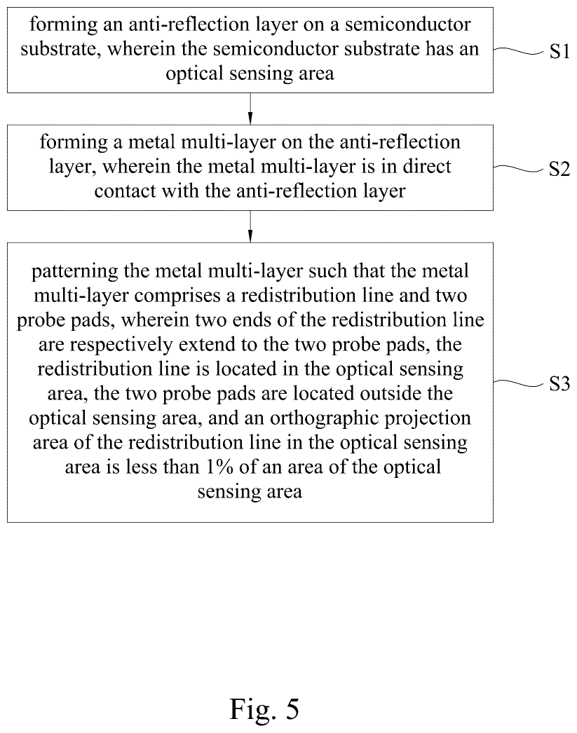

FIG. 5 is a flow chart of a manufacturing method of a chip package according to one embodiment of the present disclosure. The manufacturing method of the chip package includes the following steps. In step S1, an anti-reflection layer is formed on a semiconductor substrate, wherein the semiconductor substrate has an optical sensing area. Thereafter, in step S2, a metal multi-layer is formed on the anti-reflection layer, wherein the metal multi-layer is in direct contact with the anti-reflection layer. Subsequently, in step S3, the metal multi-layer is patterned such that the metal multi-layer includes a redistribution line and two probe pads, wherein two ends of the redistribution line are respectively extend to the two probe pads, the redistribution line is located in the optical sensing area, the two probe pads are located outside the optical sensing area, and an orthographic projection area of the redistribution line in the optical sensing area is less than 1% of an area of the optical sensing area. In addition, each of steps S1 to S3 may include plural detailed steps, the method may include other steps between step S1 and step S3, and the method may include other steps before step S1 and after step S3.

In the following description, the manufacturing method of the chip package 100 of FIG. 2 will be described in detail.

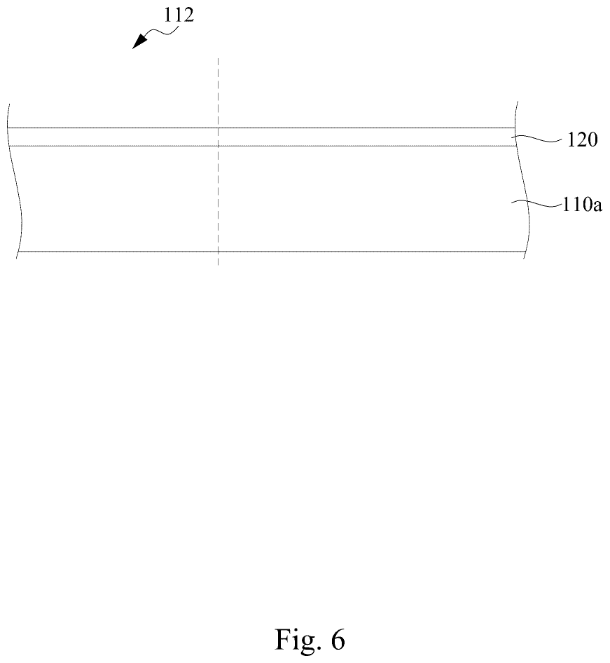

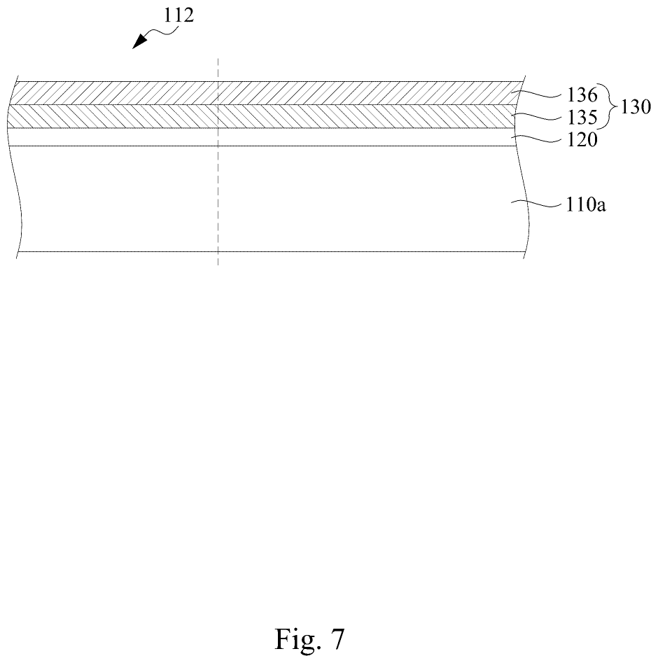

FIG. 6 to FIG. 9 are cross-sectional views at intermediate stages of the manufacturing method of the chip package 100 of FIG. 2. The cross-sectional position of FIG. 6 to FIG. 9 is the same as that of FIG. 4. The left side of the dotted line of FIGS. 6 to 9 is an area in the optical sensing area 112, and the right side of the dotted line is an area outside the optical sensing area 112. Referring to FIG. 6, the anti-reflection layer 120 may be formed on the semiconductor substrate 110a, in which the semiconductor substrate 110a is not yet diced. Referring to FIG. 7, thereafter, the metal multi-layer 130 may be formed on the anti-reflection layer 120, wherein the metal multi-layer 130 is in direct contact with the anti-reflection layer 120. The formation of the metal multi-layer 130 includes forming the lower metal layer 135 on the anti-reflection layer 120, wherein the material of the lower metal layer 135 is titanium; and forming the upper metal layer 136 on the lower metal layer 135, wherein the material of the upper metal layer 136 is gold.

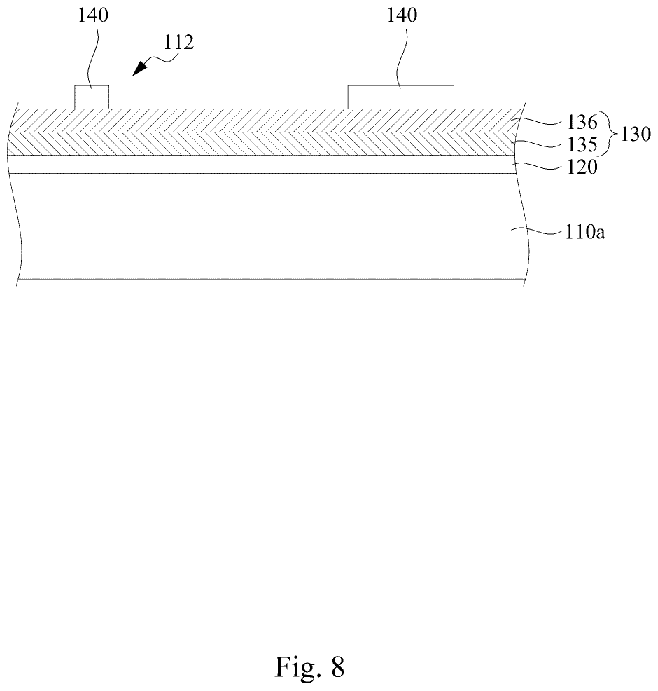

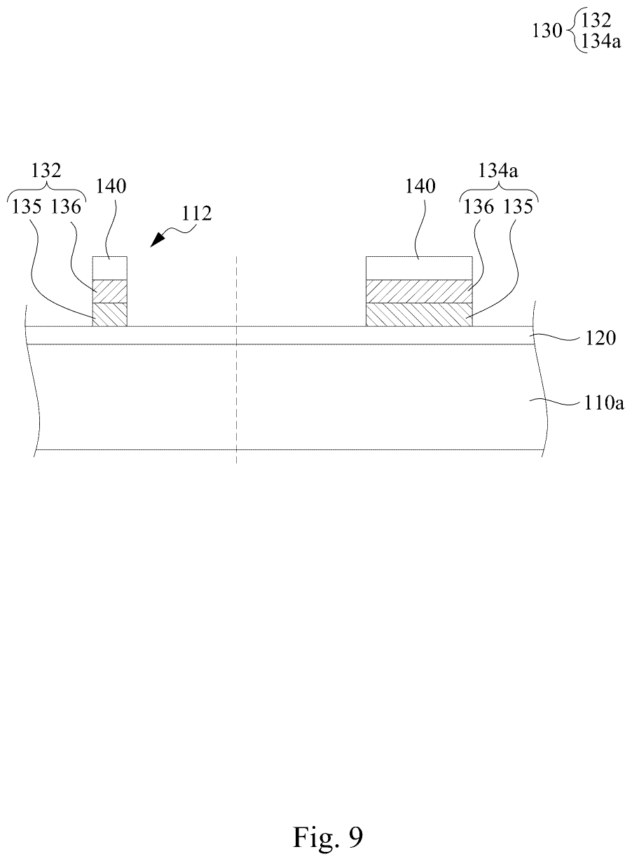

As shown in FIG. 8, after the formation of the metal multi-layer 130, a patterned photoresist layer 140 is formed on the upper metal layer 136, wherein the position of the photoresist layer 140 corresponds to the position of the redistribution line 132 and the positions of the two probe pads 134a and 134b in the aforementioned FIG. 2. As shown in FIG. 9, thereafter, the upper metal layer 136 and the lower metal layer 135 can be etched to simultaneously form the redistribution line 132 and the two probe pads 134a and 134b by using the photoresist layer 140 as a mask. Although FIG. 9 takes the probe pad 134a as an example, the structure of the probe pad 134b is also as shown in the probe pad 134a of FIG. 9. Afterwards, the photoresist layer 140 can be removed.

As shown in FIG. 2 and FIG. 9, the aforementioned step is patterning the metal multi-layer 130. By the pattern design of the photoresist layer 140, the metal multi-layer 130 can include the redistribution line 132 and the positions of the two probe pads 134a and 134b after the etch step, wherein two ends of the redistribution line 132 respectively extend to the two probe pads 134a and 134b, the redistribution line 132 is located in the optical sensing area 112, the two probe pads 134a and 134b are located outside the optical sensing area 112, and the orthographic projection area of the redistribution line 132 in the optical sensing area 112 is less than 1% of the area of the optical sensing area 112. Furthermore, patterning the metal multi-layer 130 can be performed such that the redistribution line 132 in the optical sensing area 112 is zigzag or wavy, the redistribution line 132 forms a plurality of rows, and a gap between adjacent two of the rows of the redistribution line 132 is less than 150 μm.

After the step of FIG. 9, a grinding process may be optionally performed on the bottom surface of the semiconductor substrate 110a facing away from the anti-reflection layer 120, and another anti-reflection layer may be optionally formed on the bottom surface of the semiconductor substrate 110a. Thereafter, an optical test is performed to ensure that the light transmittance of the optical sensing area 112 is greater than 99%.

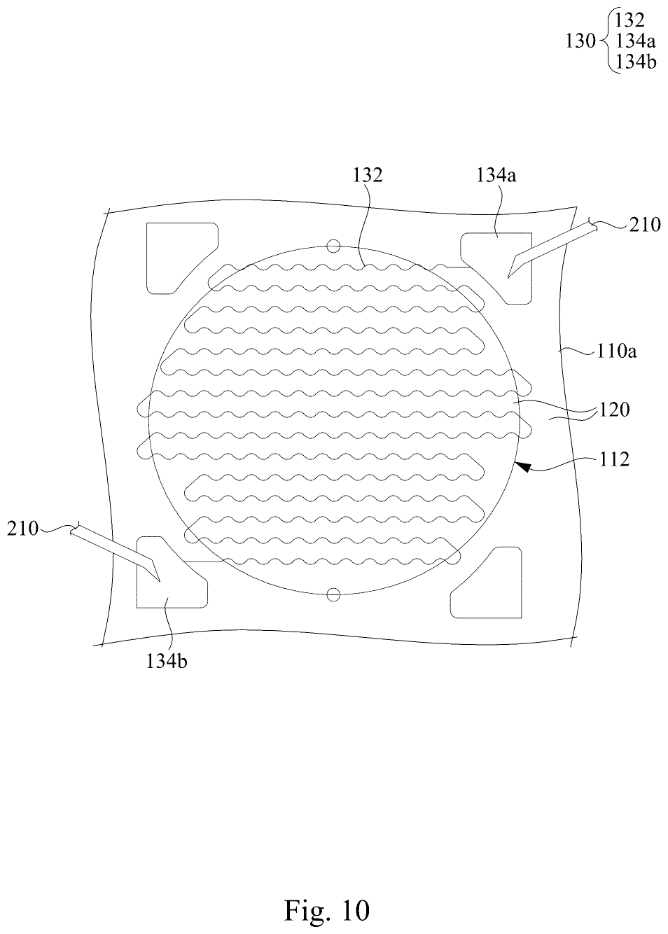

FIG. 10 is a schematic view of an operation of measuring a resistance after a structure of FIG. 9 is formed. After the optical test for the optical sensing area 112, two probes 210 may be used to respectively be in contact with the two probe pads 134a and 134b to measure the resistance of the metal multi-layer 130, thereby determining whether there is a cracked damaged area based on the measured resistance, such as the optical sensing area 112 on which the redistribution line 132 is disposed. After measuring the resistance of the metal multi-layer 130, the semiconductor substrate 110a can be diced to obtain the chip package 100 of FIG. 2.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A chip package, comprising:
a semiconductor substrate having an optical sensing area;
an anti-reflection layer located on the semiconductor substrate; and
a metal multi-layer located on and in direct contact with the anti-reflection layer, wherein the metal multi-layer comprises a redistribution line and two probe pads, two ends of the redistribution line are respectively extend to the two probe pads, the redistribution line is located in the optical sensing area, the two probe pads are located outside the optical sensing area, and an orthographic projection area of the redistribution line in the optical sensing area is less than 1% of an area of the optical sensing area.

2. The chip package of claim 1, wherein the redistribution line of the metal multi-layer comprises a plurality of rows, and a gap between adjacent two of the rows of the redistribution line is less than 150 μm.

3. The chip package of claim 1, wherein the redistribution line of the metal multi-layer is zigzag or wavy.

4. The chip package of claim 1, wherein the metal multi-layer comprises a lower metal layer and an upper metal layer, and the lower metal layer is located between the anti-reflection layer and the upper metal layer.

5. The chip package of claim 4, wherein a material of the lower metal layer is titanium, and a material of the upper metal layer is gold.

6. The chip package of claim 4, wherein a sidewall of the upper metal layer is aligned with a sidewall of the lower metal layer.

7. The chip package of claim 4, wherein the upper metal layer is separated from the anti-reflection layer.

8. A manufacturing method of a chip package, comprising:
forming an anti-reflection layer on a semiconductor substrate, wherein the semiconductor substrate has an optical sensing area;
forming a metal multi-layer on the anti-reflection layer, wherein the metal multi-layer is in direct contact with the anti-reflection layer; and
patterning the metal multi-layer such that the metal multi-layer comprises a redistribution line and two probe pads, wherein two ends of the redistribution line are respectively extend to the two probe pads, the redistribution line is located in the optical sensing area, the two probe pads are located outside the optical sensing area, and an orthographic projection area of the redistribution line in the optical sensing area is less than 1% of an area of the optical sensing area.

9. The manufacturing method of the chip package of claim 8, wherein forming the metal multi-layer on the anti-reflection layer comprises:
forming a lower metal layer on the anti-reflection layer, wherein a material of the lower metal layer is titanium; and
forming an upper metal layer on the lower metal layer, wherein a material of the upper metal layer is gold.

10. The manufacturing method of the chip package of claim 9, wherein patterning the metal multi-layer comprises:
forming a photoresist layer that is patterned on the upper metal layer, wherein a position of the photoresist layer corresponds to a position of the redistribution line and positions of the two probe pads.

11. The manufacturing method of the chip package of claim 10, wherein patterning the metal multi-layer further comprises:
etching the upper metal layer and the lower metal layer to form the redistribution line and the two probe pads by using the photoresist layer as a mask; and
removing the photoresist layer.

12. The manufacturing method of the chip package of claim 8, wherein patterning the metal multi-layer is performed such that the redistribution line comprises a plurality of rows, and a gap between adjacent two of the rows of the redistribution line is less than 150 μm.

13. The manufacturing method of the chip package of claim 8, wherein patterning the metal multi-layer is performed such that the redistribution line of the metal multi-layer is zigzag or wavy.

14. The manufacturing method of the chip package of claim 8, further comprising:
using two probes to respectively be in contact with the two probe pads to measure a resistance of the metal multi-layer.

15. The manufacturing method of the chip package of claim 14, further comprising:
after measuring the resistance of the metal multi-layer, dicing the semiconductor substrate.
